(19) United States
(12) Patent Application Publication
(10) Pub. No.: US 2026/0060075 A1
(43) Pub. Date: Feb. 26, 2026

(54) SEMICONDUCTOR DEVICE

(71) Applicant: Mitsubishi Electric Corporation, Tokyo (JP)

(72) Inventors: Hidetoshi YAMAKAWA, Tokyo (JP); Kazuki KODA, Tokyo (JP); Hiroki HIDAKA, Tokyo (JP)

(73) Assignee: Mitsubishi Electric Corporation, Tokyo (JP)

(21) Appl. No.: 19/200,283

(22) Filed: May 6, 2025

(30) Foreign Application Priority Data
Aug. 23, 2024 (JP) 2024-141998

(51) Int. Cl. H01L 23/367; H01L 23/495; H05K 7/20

(52) U.S. Cl. CPC H01L 23/3672; H01L 23/49555; H05K 7/209

(57) ABSTRACT

Provided is a semiconductor device in which breakage of a lead part caused by vibration hardly occurs. A semiconductor device includes: a semiconductor module including a plurality of lead parts; a circuit substrate connected to the plurality of lead parts of the semiconductor module; and a heatsink attached to the semiconductor module on a side opposite to a side of the circuit substrate. The plurality of lead parts include first lead parts as the lead parts disposed on both ends and second lead parts as lead parts disposed in positions other than both ends. The first lead part is thicker than the second lead part in a part between a root part as a part protruding from the semiconductor module and a connection part as a part connected to the circuit substrate.

### BACKGROUND

### Technical Field

The present disclosure relates to a semiconductor device.

### Description of the Background Art

Known as a semiconductor device used for electrical motor drive, for example, is a semiconductor device having a structure that a semiconductor module including a heatsink is mounted to a circuit substrate such as a print substrate (for example, Japanese Patent Application Laid-Open No. 2006-245620). In the semiconductor device in Japanese Patent Application Laid-Open No. 2006-245620, a protrusion for keeping an interval between the semiconductor module and the circuit substrate constant is provided to lead parts on both ends in a plurality of lead parts of the semiconductor module connected to the circuit substrate.

### SUMMARY

The semiconductor device having the above structure has a problem that vibration in transportation and vibration of a driven electrical motor are transmitted to the heatsink of the semiconductor module and cause stress in the lead part of the semiconductor module, thereby easily causing breakage of the lead part.

An object of the present disclosure is to provide a semiconductor device in which breakage of a lead part caused by vibration hardly occurs.

A semiconductor device according to the present disclosure includes: a semiconductor module including a plurality of lead parts; a circuit substrate connected to the plurality of lead parts of the semiconductor module; and a heatsink attached to the semiconductor module on a side opposite to a side of the circuit substrate. The plurality of lead parts include first lead parts as the lead parts disposed on both ends and second lead parts as the lead parts disposed in positions other than the both ends. Each of the first lead parts is thicker than each of the second lead parts in a part between a root part as a part protruding from the semiconductor module and a connection part as a part connected to the circuit substrate.

According to the semiconductor device in the present disclosure, breakage of the lead part caused by vibration can be prevented.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a front view illustrating a configuration of a semiconductor device according to an embodiment 1.

FIG. 2 is a side view illustrating a configuration of the semiconductor device according to the embodiment 1.

FIG. 3 is a front view illustrating a modification example of the semiconductor device according to the embodiment 1.

FIG. 4 is a front view illustrating a modification example of the semiconductor device according to the embodiment 1.

FIG. 5 is a front view illustrating a modification example of the semiconductor device according to the embodiment 1.

FIG. 6 is a side view illustrating a configuration of a semiconductor device according to an embodiment 2.

FIG. 7 is a side view illustrating a configuration of the semiconductor device according to the embodiment 2.

FIG. 8 is a front view illustrating a configuration of a semiconductor device according to an embodiment 3.

FIG. 9 is a front view illustrating a configuration of a semiconductor device according to an embodiment 4.

FIG. 10 is a side view illustrating a configuration of the semiconductor device according to the embodiment 4.

FIG. 11 is a side view illustrating a modification example of the semiconductor device according to the embodiment 4.

FIG. 12 is a front view illustrating a configuration of a semiconductor device according to an embodiment 5.

FIG. 13 is a front view illustrating a modification example of the semiconductor device according to the embodiment 5.

FIG. 14 is a front view illustrating a modification example of the semiconductor device according to the embodiment 5.

FIG. 15 is a front view illustrating a configuration of a semiconductor device according to an embodiment 6.

FIG. 16 is a front view illustrating a configuration of a semiconductor device according to an embodiment 7.

### DESCRIPTION OF THE PREFERRED EMBODIMENTS

### Embodiment 1

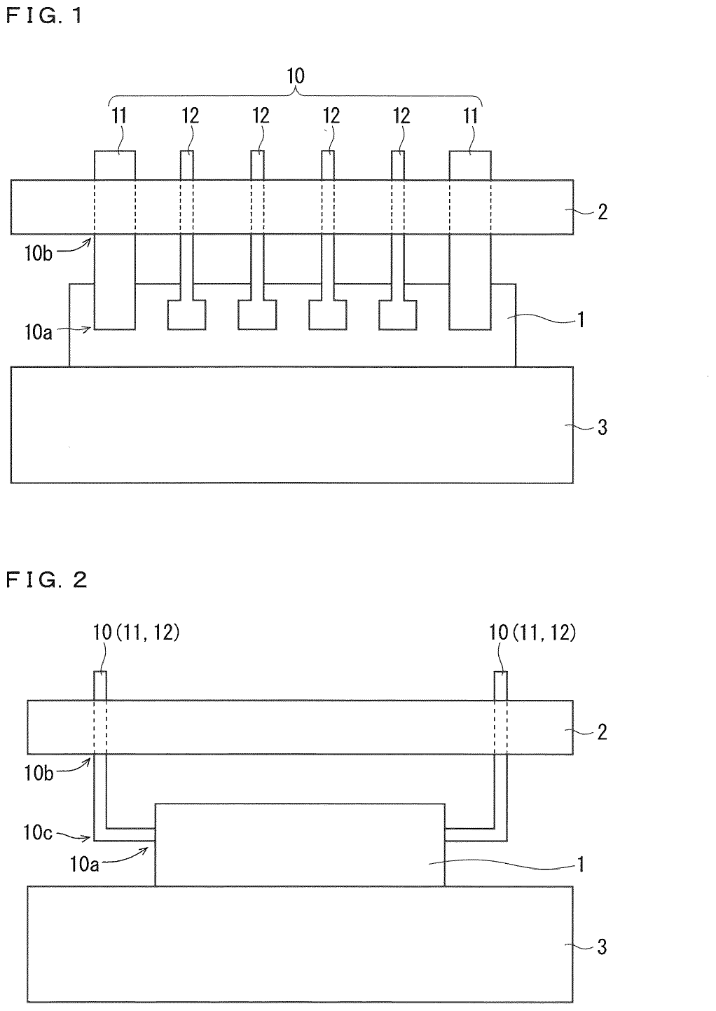

FIG. 1 and FIG. 2 are diagrams each illustrating a configuration of a semiconductor device according to an embodiment 1. FIG. 1 and FIG. 2 illustrate a configuration of the same semiconductor device seen from directions different from each other by 90 degrees. A diagram corresponding to FIG. 1 is referred to as “front view”, and a diagram corresponding to FIG. 2 is referred to as “side view” hereinafter for convenience of description.

As illustrated in FIG. 1 and FIG. 2, the semiconductor device according to the embodiment 1 includes a semiconductor module 1, a circuit substrate 2, and a heatsink 3.

The semiconductor module 1 includes a plurality of lead parts 10. The circuit substrate 2 is connected to the plurality of lead parts 10 of the semiconductor module 1. The heatsink 3 is attached to a surface of the semiconductor module 1 on a side opposite to a side of the circuit substrate 2. The semiconductor module 1 is a semiconductor module for controlling electrical power (a so-called power module), for example. The circuit substrate 2 is a printed circuit board (PCB), for example.

Herein, the lead parts 10 disposed on both ends in the plurality of lead parts 10 of the semiconductor module 1 are defined as “first lead parts 11”, and the lead parts 10 disposed in positions other than both ends are defined as “second lead parts 12”. “The lead part 10” in the description hereinafter indicates both the first lead part 11 and the second lead part 12.

In each of the plurality of lead parts 10 (the first lead part 11 and the second lead part 12), a part protruding from the semiconductor module 1 is defined as “a root part 10a”, a part connected to the circuit substrate 2 is defined as “a connection part 10b”, and a bending part between the root part 10a and the connection part 10b is defined as “a bending part 10c”.

In the semiconductor device according to the embodiment 1, the first lead part 11 is thicker than the second lead part 12. A thickness of the first lead part 11 and a thickness of the second lead part 12 are the same as each other in the present embodiment. A width of the first lead part 11 is larger than that of the second lead part 12; thus, the first lead part 11 is thicker than the second lead part 12.

The first lead part 11 has higher resistance against stress because of thickness, and is hardly broken. Since the first lead parts 11 disposed on both ends are thick, transmission of vibration of the heatsink 3 caused by vibration in transportation and vibration of a driven electrical motor to the second lead part 12 can be suppressed, and breakage of the second lead part 12 by stress caused by the vibration is also prevented. According to the semiconductor device in the present disclosure, achieved is an effect that breakage of the lead part 10 caused by vibration hardly occurs.

The first lead part 11 may be a lead part actually used for controlling the semiconductor module 1, or may also be a dummy lead part provided for a purpose of mainly holding the circuit substrate 2.

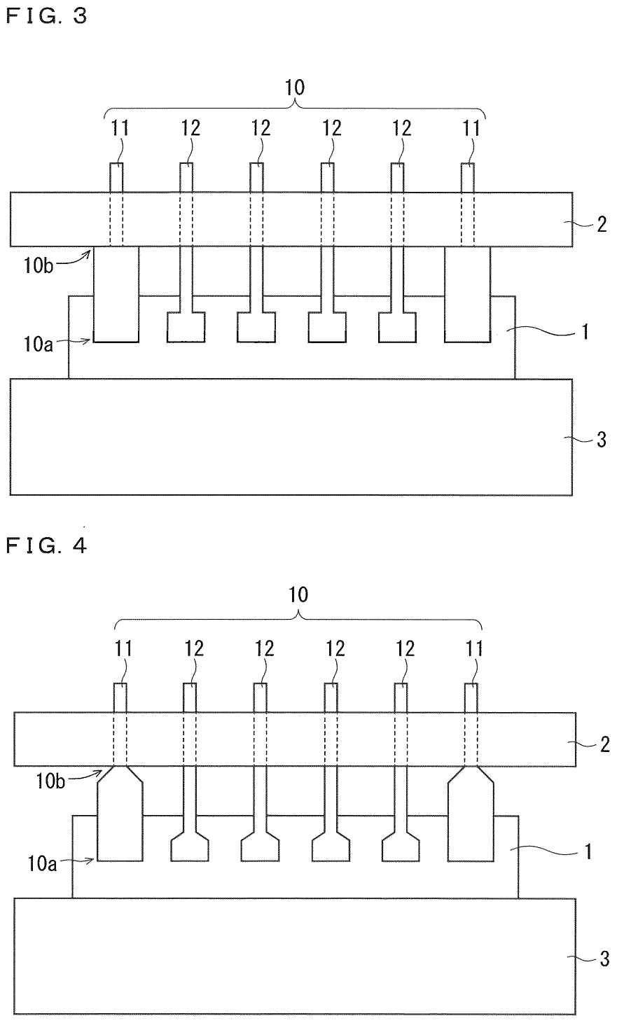

It is sufficient that the first lead part 11 is thicker than the second lead part 12 at least in a part between the root part 10a and the connection part 10b. For example, as illustrated by a front view in FIG. 3, the first lead part 11 may have the same thickness (width) as the second lead part 12 in a part closer to a distal end in relation to the connection part 10b. That is to say, the first lead part 11 includes a part with a large width from the root part 10a to the connection part 10b and a part with a small width closer to the distal end in relation to the connection part 10b. The part of the lead part 10 with the large width (the first lead part 11 and the second lead part 12) is referred to as “a large-width part” and a part thereof with the small width is referred to as “a small-width part” hereinafter.

In FIG. 3, the large-width part and the small-width part are provided to not only the first lead part 11 but also the second lead part 12. The large-width part has larger resistance against stress than the small-width part. In the meanwhile, stress tends to be concentrated in the bending part 10c. Thus, the bending part 10c of each lead part 10 is preferably located in the large-width part.

In the configuration in FIG. 3, a level difference at a boundary between the large-width part and the small-width part of the first lead part 11 can be used as a protrusion keeping an interval between the semiconductor module 1 and the circuit substrate 2 constant. That is to say, when a position of the boundary between the large-width part and the small-width part of the first lead part 11 is adjusted, the interval between the semiconductor module 1 and the circuit substrate 2 can be adjusted.

However, stress tends to occur in a part of the level difference at the boundary between the large-width part and the small-width part of the lead part 10. An inclination part in which the width of the lead part 10 is gradually changed may be provided to a boundary part between the large-width part and the small-width part as illustrated in FIG. 4 to reduce concentration of this stress.

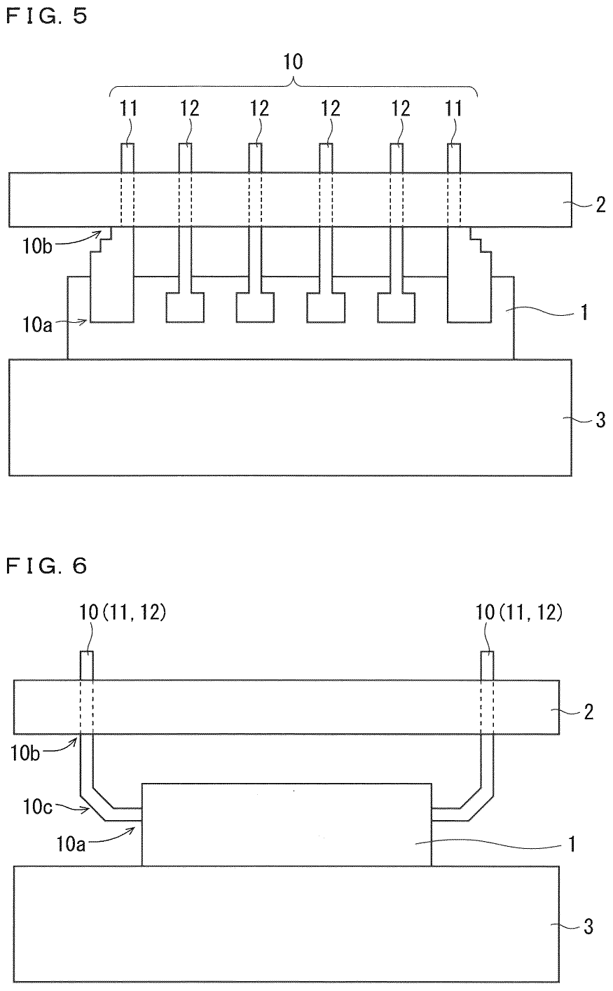

A step-like part in which the width is changed in stages may be provided to the boundary part between the large-width part and the small-width part of the first lead part 11 as illustrated in FIG. 5. In this case, the interval between the semiconductor module 1 and the circuit substrate 2 can be adjusted by a position or a size of a through hole into which the first lead part 11 is inserted in the circuit substrate 2.

### Embodiment 2

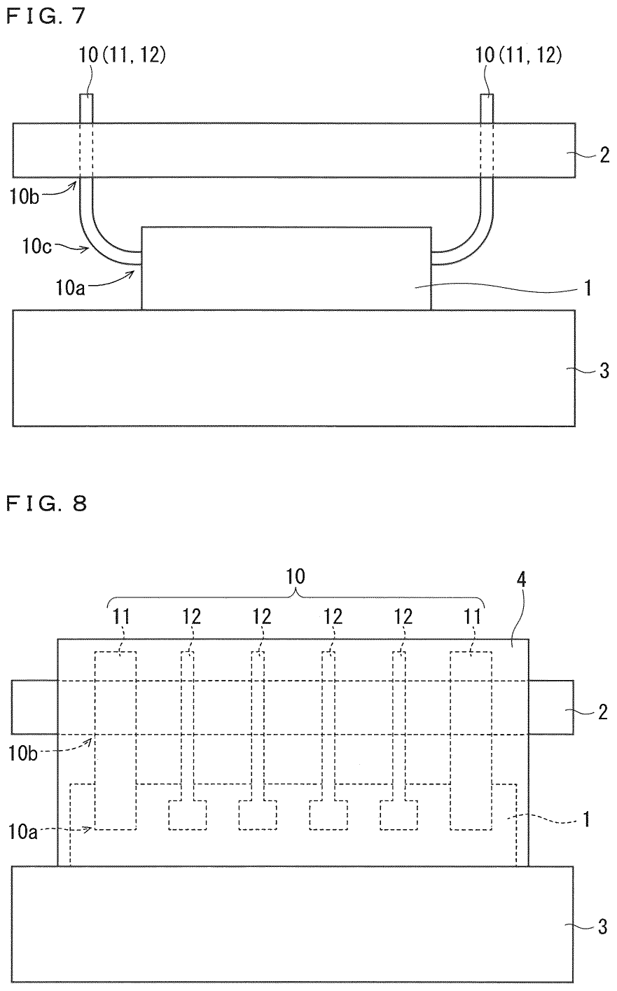

FIG. 6 and FIG. 7 are side views each illustrating a configuration of a semiconductor device according to an embodiment 2. A front view of the semiconductor device according to the embodiment 2 is the same as that in FIG. 1. The configuration of the semiconductor device according the embodiment 2 is different from that according to the embodiment 1 in that a shape of the bending part 10c of the lead part 10 is changed.

As described above, the stress tends to be concentrated in the bending part 10c of the lead part 10. Thus, in the embodiment 2, the bending part 10c of the lead part 10 has a shape bended in stages as illustrated in FIG. 6. The bending part 10c of the lead part 10 may have a shape bended into an arc-like shape as illustrated in FIG. 7.

In this manner, when the bending part 10c has the shape bended in the arc-like shape or in stages, concentration of the stress in the bending part 10c is reduced, and an effect of preventing breakage of the lead part 10 is improved. Also in the present embodiment, the bending part 10c of each lead part 10 is preferably located in the large-width part.

### Embodiment 3

FIG. 8 is a front view illustrating a configuration of a semiconductor device according to an embodiment 3. The configuration of the semiconductor device according the embodiment 3 is different from that according to the embodiment 1 in that a resin member 4 covering the plurality of lead parts 10 is added.

The resin member 4 needs not cover the whole plurality of lead parts 10; however, it is sufficient that the resin member 4 covers at least some of the plurality of lead parts 10. That is to say, the lead part 10 which is not covered by the resin member 4 may be included, and part (a distal end part, for example) the lead part 10 may be exposed from the resin member 4. The resin member 4 may cover the whole the semiconductor module 1 and circuit substrate 2.

According to the semiconductor device in the embodiment 3, since vibration of the lead part 10 is suppressed by the resin member 4, an effect of preventing breakage of the lead part 10 is improved.

### Embodiment 4

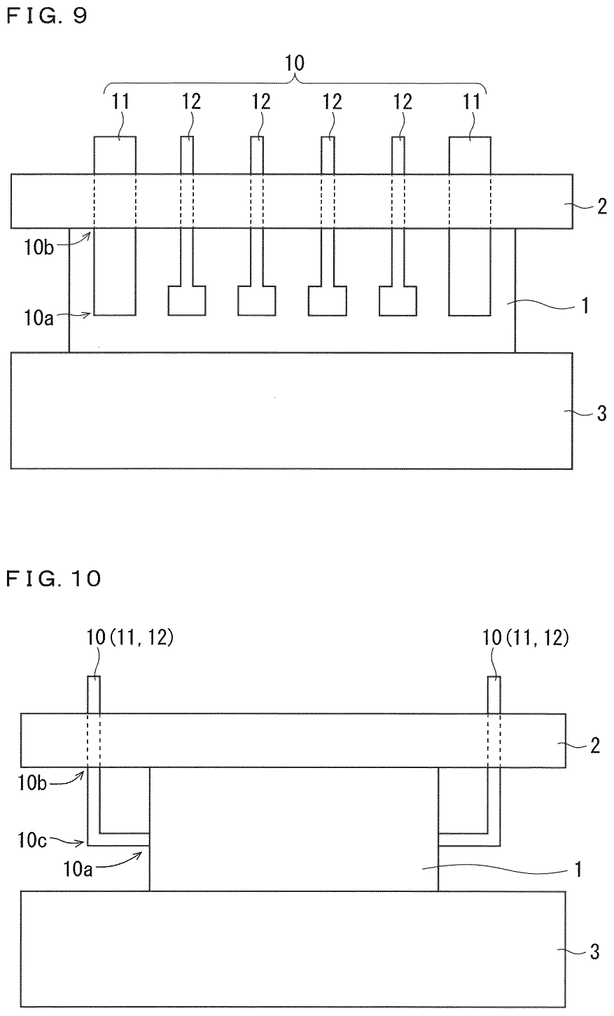

FIG. 9 and FIG. 10 are a front view and a side view each illustrating a configuration of a semiconductor device according to an embodiment 4. The configuration of the semiconductor device according to the embodiment 4 is different from that according to the embodiment 1 in that a gap between the semiconductor module 1 and the circuit substrate 2 is omitted.

Although the gap is provided between the semiconductor module 1 and the circuit substrate 2 in the embodiments 1 to 3, the gap is not provided between the semiconductor module 1 and the circuit substrate 2 in the embodiment 4. That is to say, in the embodiment 4, the circuit substrate 2 is bonded to the plurality of lead parts 10 while having contact with an upper surface (that is to say, a surface facing the circuit substrate 2) of the semiconductor module 1.

According to the semiconductor device in the embodiment 4, since vibration of the lead part 10 is suppressed by contact between the semiconductor module 1 and the circuit substrate 2, an effect of preventing breakage of the lead part 10 is improved.

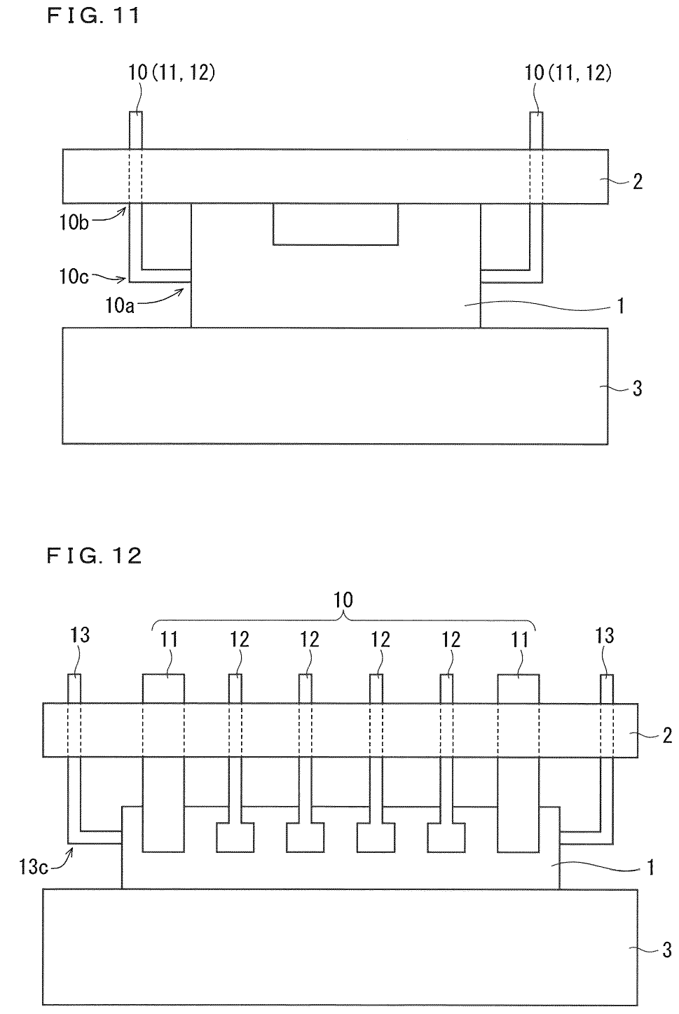

FIG. 9 and FIG. 10 illustrate an example that the upper surface of the semiconductor module 1 is flat and the whole upper surface of the semiconductor module 1 has contact with the circuit substrate 2. However, as illustrated by a side view in FIG. 11, it is also applicable that the upper surface of the semiconductor module 1 has unevenness, and partially has contact with the circuit substrate 2.

FIG. 9 and FIG. 10 illustrate an example that molding resin forming an outer shape of the semiconductor module 1 is thickened to omit the gap between the semiconductor module 1 and the circuit substrate 2. However, the molding resin needs not be thickened when the circuit substrate 2 can have contact with the upper surface of the semiconductor module 1.

### Embodiment 5

FIG. 12 is a front view illustrating a configuration of a semiconductor device according to an embodiment 5. The configuration of the semiconductor device according to the embodiment 5 is different from that according to the embodiment 1 in that a third lead part 13 different from the lead part 10 is provided to the semiconductor module 1.

The third lead part 13 protrudes from a side surface (that is to say, a surface thereof different from the surface from which the lead part 10 protrudes) of the semiconductor module 1, and is connected to the circuit substrate 2. The third lead part 13 may be a lead part actually used for controlling the semiconductor module 1, or may also be a dummy lead part provided for a purpose of mainly holding the circuit substrate 2.

According to the semiconductor device in the embodiment 5, since the third lead part 13 suppresses vibration of the lead part 10 in a lateral direction, an effect of preventing breakage of the lead part 10 is improved.

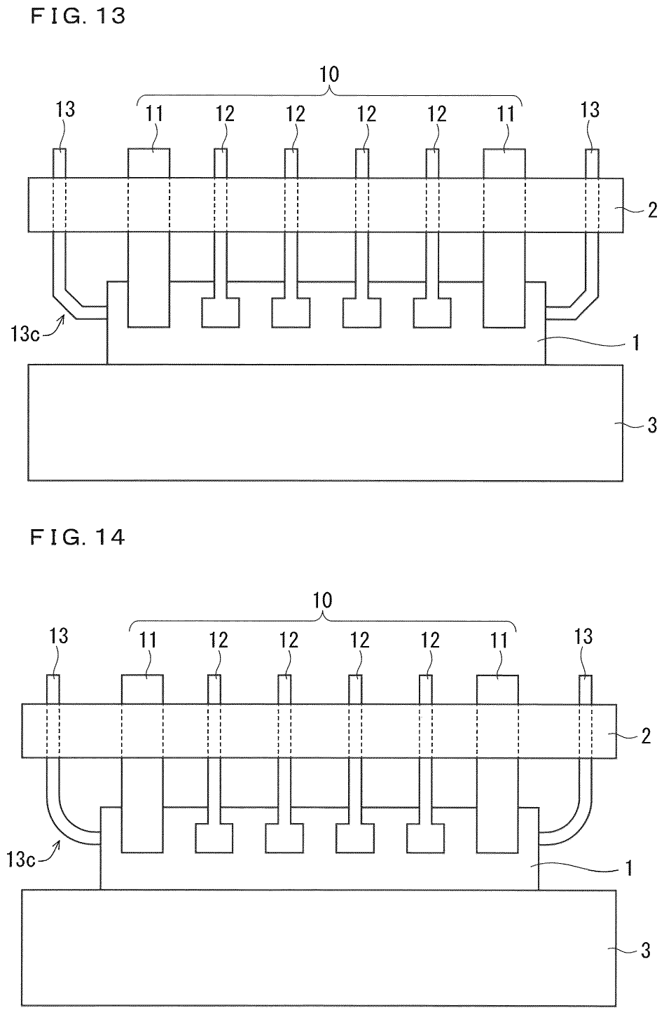

The embodiment 2 may be applied to the third lead part 13. That is to say, a bending part 13c of the third lead part 13 may have a shape bended in stages as illustrated in FIG. 13 or a shape bended into an arc-like shape as illustrated in FIG. 14. Accordingly, breakage of the third lead part 13 can also be suppressed.

### Embodiment 6

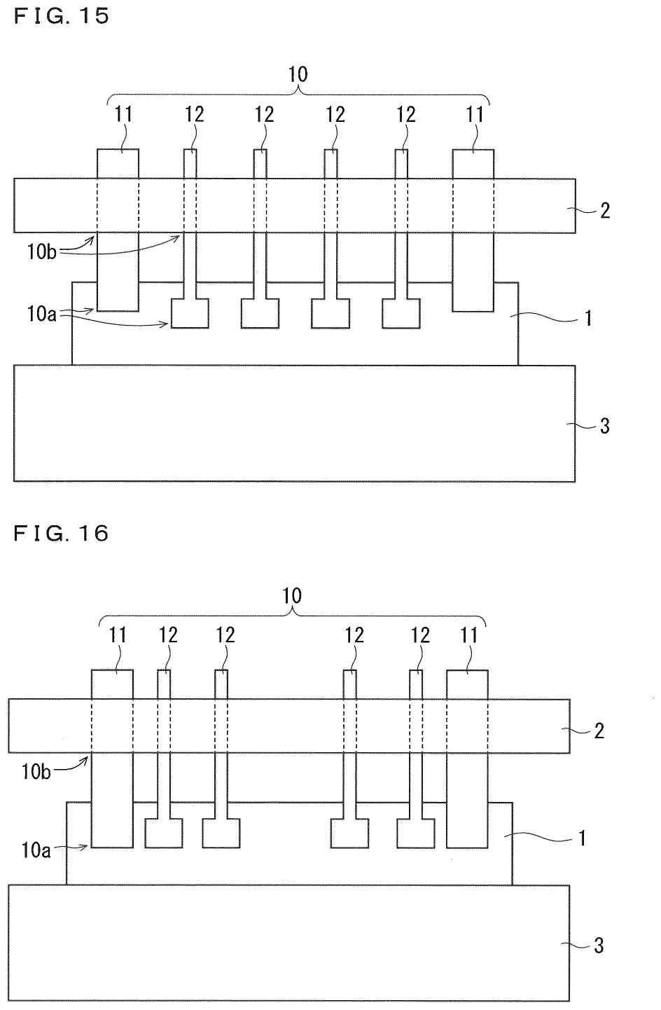

FIG. 15 is a front view illustrating a configuration of a semiconductor device according to an embodiment 6. The configuration of the semiconductor device according to the embodiment 6 is different from that according to the embodiment 1 in that a position of the root part 10a of the first lead part 11 is disposed closer to the circuit substrate 2 (farther away from the heatsink 3) than the root part 10a of the second lead part 12.

In the embodiment 6, a distance from the root part 10a of the first lead part 11 to the connection part 10b is smaller than that from the root part 10a of the second lead part 12 to the connection part 10b. Improved accordingly is an effect of the first lead part 11 that vibration of the heatsink 3 is hardly transmitted to the second lead part 12, and an effect of preventing breakage of the lead part 10 caused by vibration is improved.

### Embodiment 7

FIG. 16 is a front view illustrating a configuration of a semiconductor device according to an embodiment 7. The configuration of the semiconductor device according the embodiment 7 is different from that according to the embodiment 1 in that an interval between the lead parts 10 is changed.

In the embodiment 7, the interval between the lead part 10 is smaller in an outer side than in a center part. That is to say, the interval between the lead parts 10 disposed on the outer side in the plurality of lead parts 10 is smaller than that between the lead parts 10 disposed in the center part.

More stress by vibration tends to be applied to the lead part 10 disposed on the outer side. When the interval between the lead parts 10 on the outer side gets smaller, an effect of reducing the stress applied to the lead part 10 on the outer side can be expected.

Each embodiment can be arbitrarily combined, or each embodiment can be appropriately varied or omitted.

### APPENDIX

The aspects of the present disclosure are collectively described hereinafter as appendixes.

### Appendix 1

A semiconductor device, comprising:
a semiconductor module including a plurality of lead parts;
a circuit substrate connected to the plurality of lead parts of the semiconductor module; and
a heatsink attached to the semiconductor module on a side opposite to a side of the circuit substrate, wherein
the plurality of lead parts include:
first lead parts as the lead parts disposed on both ends; and
second lead parts as the lead parts disposed in positions other than the both ends, and
each of the first lead parts is thicker than each of the second lead parts in a part between a root part as a part protruding from the semiconductor module and a connection part as a part connected to the circuit substrate.

### Appendix 2

The semiconductor device according to Appendix 1, wherein
each of the first lead parts includes a large-width part from the root part to the connection part and a small-width part closer to a distal end in relation to the connection part.

### Appendix 3

The semiconductor device according to Appendix 2, wherein
each of the first lead parts includes an inclination part in which a width of each of the lead parts is gradually changed at a boundary between the large-width part and the small-width part.

### Appendix 4

The semiconductor device according to Appendix 2, wherein
each of the first lead parts includes a step-like part in which a width of each of the lead parts is changed in stages at a boundary between the large-width part and the small-width part.

### Appendix 5

The semiconductor device according to any one of Appendixes 1 to 4, wherein
a distance from the root part to the connection part of each of the first lead parts is smaller than a distance from the root part to the connection part of each of the second lead parts.

### Appendix 6

The semiconductor device according to any one of Appendixes 1 to 5, wherein
each of the plurality of lead parts includes a large-width part including the root part and a small-width part including the connection part, and also includes an inclination part in which a width of each of the lead parts is gradually changed at a boundary between the large-width part and the small-width part.

### Appendix 7

The semiconductor device according to any one of Appendixes 1 to 6, wherein
each of the plurality of lead parts includes a bending part bended into an arc-like shape or in stages.

### Appendix 8

The semiconductor device according to any one of Appendixes 1 to 6, wherein
each of the plurality of lead parts includes a large-width part including the root part and a small-width part including the connection part, and also includes a bending part in the large-width part.

### Appendix 9

The semiconductor device according to Appendix 8, wherein
each of the plurality of lead parts is bended into an arc-like shape or in stages in the bending part.

### Appendix 10

The semiconductor device according to any one of Appendixes 1 to 9, further comprising
a resin member covering at least some of the plurality of lead parts.

### Appendix 11

The semiconductor device according to any one of Appendixes 1 to 10, wherein
the circuit substrate is bonded to the plurality of lead parts while having contact with a surface of the semiconductor module facing the circuit substrate.

### Appendix 12

The semiconductor device according to any one of Appendixes 1 to 11, wherein
the semiconductor module further includes a third lead part protruding from a surface different from the surface from which the plurality of lead parts protrude, and
the third lead part is connected to the circuit substrate.

### Appendix 13

The semiconductor device according to Appendix 12, wherein
the third lead part includes a bending part bended into an arc-like shape or in stages.

### Appendix 14

The semiconductor device according to any one of Appendixes 1 to 13, wherein
an interval between the plurality of lead parts is smaller in an outer side than in a center part.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor module including a plurality of lead parts;
a circuit substrate connected to the plurality of lead parts of the semiconductor module; and
a heatsink attached to the semiconductor module on a side opposite to a side of the circuit substrate, wherein
the plurality of lead parts include:
first lead parts as the lead parts disposed on both ends; and
second lead parts as the lead parts disposed in positions other than the both ends, and
each of the first lead parts is thicker than each of the second lead parts in a part between a root part as a part protruding from the semiconductor module and a connection part as a part connected to the circuit substrate.

2. The semiconductor device according to claim 1, wherein
each of the first lead parts includes a large-width part from the root part to the connection part and a small-width part closer to a distal end in relation to the connection part.

3. The semiconductor device according to claim 2, wherein
each of the first lead parts includes an inclination part in which a width of each of the lead parts is gradually changed at a boundary between the large-width part and the small-width part.

4. The semiconductor device according to claim 2, wherein
each of the first lead parts includes a step-like part in which a width of each of the lead parts is changed in stages at a boundary between the large-width part and the small-width part.

5. The semiconductor device according to claim 1, wherein
a distance from the root part to the connection part of each of the first lead parts is smaller than a distance from the root part to the connection part of each of the second lead parts.

6. The semiconductor device according to claim 1, wherein
each of the plurality of lead parts includes a large-width part including the root part and a small-width part including the connection part, and also includes an inclination part in which a width of each of the lead parts is gradually changed at a boundary between the large-width part and the small-width part.

7. The semiconductor device according to claim 1, wherein
each of the plurality of lead parts includes a bending part bended into an arc-like shape or in stages.

8. The semiconductor device according to claim 1, wherein
each of the plurality of lead parts includes a large-width part including the root part and a small-width part including the connection part, and also includes a bending part in the large-width part.

9. The semiconductor device according to claim 8, wherein
each of the plurality of lead parts is bended into an arc-like shape or in stages in the bending part.

10. The semiconductor device according to claim 1, further comprising
a resin member covering at least some of the plurality of lead parts.

11. The semiconductor device according to claim 1, wherein
the circuit substrate is bonded to the plurality of lead parts while having contact with a surface of the semiconductor module facing the circuit substrate.

12. The semiconductor device according to claim 1, wherein
the semiconductor module further includes a third lead part protruding from a surface different from the surface from which the plurality of lead parts protrude, and
the third lead part is connected to the circuit substrate.

13. The semiconductor device according to claim 12, wherein
the third lead part includes a bending part bended into an arc-like shape or in stages.

14. The semiconductor device according to claim 1, wherein
an interval between the plurality of lead parts is smaller in an outer side than in a center part.
